(19) United States
(12) Patent Application Publication
(10) Pub. No.: US 2007/0114663 A1
(43) Pub. Date: May 24, 2007

(54) Alloys for flip chip interconnects and bumps

(76) Inventors: Derrick L. Brown, Beamsville (CA); Heiner Lichtenberger, Williamsville, NY (US)

Correspondence Address: PHILLIPS LYTLE LLP;INTELLECTUAL PROPERTY GROUP, 3400 HSBC CENTER, BUFFALO, NY, 14203-3509, US

(21) Appl. No.: 11/603,400

(22) Filed: Nov. 22, 2006

Related U.S. Application Data
(60) Provisional application No. 60/739,584, filed on Nov. 23, 2005.

(51) Int. Cl. H01L 23/48

(52) U.S. Cl. 257/737

(57) ABSTRACT

The present invention provides alloys for forming sputtered under bump metallization seed layers and electroplated or otherwise deposited bump metallurgy. The alloys of the present invention are comprised of silver with gold or palladium, copper with gold, or gold with nickel or palladium which provide suitable sputtering and electrical characteristics and resistance to corrosion and tarnishing. The invention further provides for semiconductor devices made from metal alloys for UBM and bump metallurgy, and for a method of making such semiconductor devices.

### PRIORITY CLAIM

The present application claims priority to Provisional Patent Application No. 60/739,584, filed Nov. 23, 2005.

### TECHNICAL FIELD

The present invention relates to flip chip semiconductor devices and, more particularly, to the materials in the metal bumps of flip chip devices, especially alloys of silver, copper and/or gold metals.

### BACKGROUND OF THE INVENTION

Currently, gold posts are electroplated onto aluminum, copper or gold electrical junctions on semiconductor devices employing an under bump metallization (UBM) which acts as a diffusion barrier between the semiconductor input/output (I/O) and the bump metallurgy, protects the I/O layer from the atmosphere and acts as a seed layer for an electroplated metal that comprises the bump. Flip chip devices have been marketed for many years and are basically found in two forms. The most common form employs an aluminum semiconductor contact that is sputter coated with chromium or titanium as an adhesion layer followed with a sputtered nickel anti-diffusion layer, and capped with a copper electroplated layer. The chrome or titanium, nickel and copper layers form the UBM. Solder would be electroplated onto the UBM layer, then reflowed to form 0.004″ diameter (100 micron) balls or bumps. Subsequently these solder balls will be reflowed as the flip chip device is mounted onto a customized printed circuit board (PCB).

Flip chip semiconductors offer the advantage of better heat dissipation through the metal connections, shorter circuitry versus bonding wire interconnections for higher speed devices and significantly smaller size than conventional semiconductors. Many flip chip devices can be mounted onto a single PCB to accomplish the electronic purpose of the electronic device.

Flip chip technology may be used advantageously in electronic watches, cell phones, TFT/LCD drivers and displays, pagers and high speed microprocessors, for example, and other products and devices.

As electronic devices continue to become more complex and smaller, these semiconductors require more I/O connections and the bumps must get closer together than solder bump methods allow. Currently, such high level flip chips incorporate a metallization format of aluminum, gold or copper electrical lands that are part of the semiconductor circuitry and serve as I/O junctions, and a UBM of sputtered titanium tungsten alloy topped off with a sputtered layer of pure gold. Sputtering is accomplished in a vacuum chamber where a cathode of the gold or metal alloy is placed near the semiconductor device, which is the anode in this circuit, and as a voltage potential and a magnetic field is applied, a plasma is developed which propels atoms of the cathode material toward the anode. In this way pure metals as well as metal alloys can be coated on an atom by atom basis onto a substrate. Typical UBM layers comprise very thin metal layers where the thickness can be measured by several hundred atom layers, or about 1,500 to 4,500 angstroms in scientific terms. This UBM is required to allow for electroplating since an inert and chemically stable metal or alloy is required. Pure gold is then electroplated onto the sputtered gold seed layer. The gold bumps can be as small as 15 microns (0.0006″) in height and on centerline spacings of 45 microns (less than 0.002″). During bonding onto a printed circuit board these bumps are typically reduced to one half their original height. Various masking techniques are used throughout the metallization processes to insure that the metals are deposited n the correct places. The construction of these metal bumps is illustrated in FIGS. 1 and 2, which show the construction of solder and gold bumps. FIG. 1 illustrates the 6 step method for applying solder to the metallized pad on the semiconductor, including masking methods, solder electroplating, mask removal and solder reflow under heat. FIG. 2 illustrates the 6 steps to make a gold bump on a semiconductor device including passivation of the surface, masking, exposure, UBM deposition, gold electroplating and removal of the mask.

Environmental testing for flip chip devices follows standard semiconductor materials testing formats and includes: temperature cycling from −65C to +150 C for 1000 cycles; pressure cooker at 121 C, 2 atm 100 % RH for 240 hours; high temperature storage at 125 C for 1000 hours, as well thermal shock and vibration tests.

Gold is the chosen metal for creation of high density I/O bumps because of its ability to make tall narrow structures, its familiarity in the semiconductor industry, its corrosion resistance and its ability to be thermal compressive bonded onto a gold plated circuit placed on glass, ceramic or plastic. While gold performs excellently it suffers from very high cost. Aluminum has system compatibility, but it cannot be made into tall and narrow structures that form the bumps of the flip chip device. Copper and silver, like gold, have excellent sputtering and electroplating characteristics, but their corrosion resistance is inadequate for them to be reliably bonded onto gold plated circuitry.

There is an ongoing need to reduce the cost of pure gold in flip chip devices and to create alloys with uniform sputtering characteristics and improved corrosion resistance. This need is met by the alloys of the present invention, whose sputtering and corrosion resistance characteristics make them especially suitable for use as UBM and bump materials in flip chip semiconductor devices.

### BRIEF SUMMARY OF THE INVENTION

The present invention is directed to silver, copper and gold alloys useful for forming UBM and electroplated metal bumps (e.g. bump and/or UBM alloys of silver and gold, silver and palladium, silver, gold and palladium, copper and gold, gold and nickel, gold and palladium, and gold, nickel, and palladium). Silver alloyed with gold improves the tarnish resistance of pure silver while still maintaining a soft and compliant alloy suitable for thermo-sonic bonding to gold plated circuitry. While certain of the herein described silver alloys contain gold, the cost of silver is significantly less than the cost of gold, and the silver alloys of this invention are typically less than 80% of the metal cost of pure gold.

In another aspect of this invention, copper is alloyed with gold. This combination is quite corrosion resistant, compatible will all materials in these flip chip devices and markedly less expensive. The invention is further directed to the use of gold and silver alloys in the UBM sputtered metal layers and the electroplated bump metals. Other aspects of the invention are directed to semiconductor devices with various bump and/or UBM alloys of silver and gold, silver and palladium, silver, gold and palladium, copper and gold, gold and nickel, gold and palladium, and gold, nickel, and palladium.

Accordingly, the general object of the invention is to provide bumps and UBM seed layers, and semiconductor devices having such bumps and UBM seed layers, with improved alloy compositions. Another object is to provide bumps and UBM's with alloy compositions which are less expensive than pure gold. Yet another object is to provide alloy compositions for bumps and UBM seed layers which are sufficiently corrosion and/or tarnish resistant. Still another object is to provide bumps and UBM's with alloy compositions with properties which simulate the electrical and/or corrosion resistant properties of gold.

These and other objects and advantages will become apparent from the foregoing and ongoing written specification, the drawings, and the appended claims.

### BRIEF DESCRIPTION OF THE DRAWINGS

FIG. 1 is a schematic representation of how a solder bump is attached to a semiconductor device.

FIG. 2 is a schematic representation of how a gold bump is attached to a semiconductor device.

FIG. 3 illustrates a completed solder bump on a flip chip after the solder is reflowed to make a spherical bump.

FIG. 4 illustrates gold bumps on a flip chip device.

FIG. 5 illustrates the size and dimensions of example solder and gold bumps showing the greater density of I/O interconnects with the gold bumping method.

### DESCRIPTION OF THE PREFERRED EMBODIMENTS

Pure silver has insufficient corrosion resistance to be used as the bump material, but with the addition of small amounts of gold and/or palladium the tarnish resistance is markedly improved. Pure silver also has a tendency towards electro-migration that can short out electrical interconnections, but this problem is cured by alloying with gold or palladium.

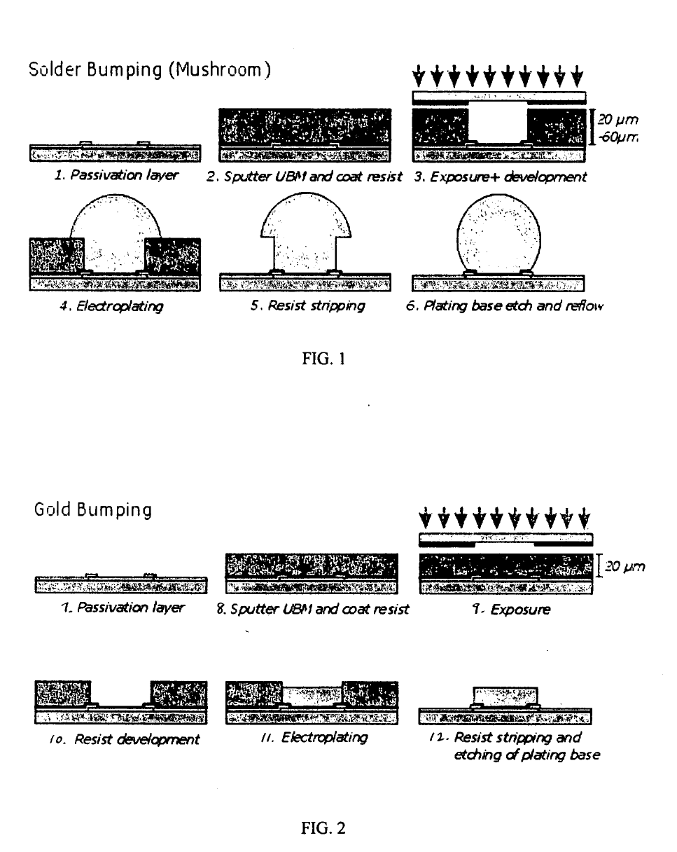

FIG. 1 depicts the 6 main steps in making a solder bump including passivation 1, sputter UBM and coat with resist 2, exposure and development of the resist 3, electroplating the solder 4, striping the resist 5 and finally reflowing the irregularly shaped solder into a sphere 6. This bump is now ready to be reflowed once more onto a gold plated circuit. FIG. 2 illustrates the 6 steps to make a gold or alloy bump on a semiconductor device including passivation of the surface 7, masking 8, exposure 9, UBM deposition 10, gold electroplating 11 and removal of the mask 12.

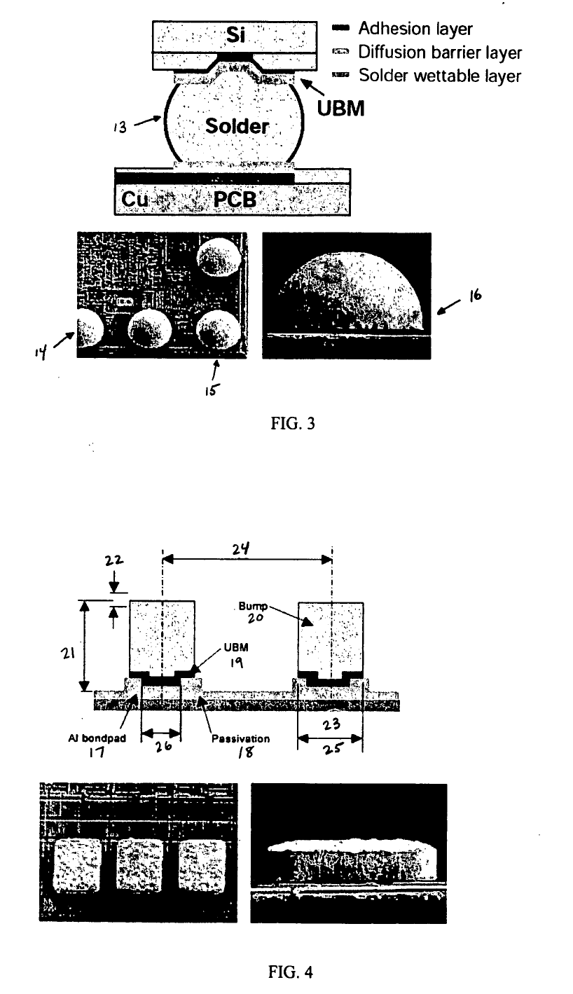

FIG. 3 illustrates a solder bump 13 after reflowing onto a printed circuit board and also the bumps 14, 15, 16 as they appear on the surface of the flip chip device.

FIG. 4 shows gold or alloy bumps on a flip chip device. The aluminum I/O with UBM sputtered onto it 17, the passivation layer on the bulk of the semiconductor device 18, the UBM layer 19, the electroplated bump 20 and the key dimensions 21-26 are shown.

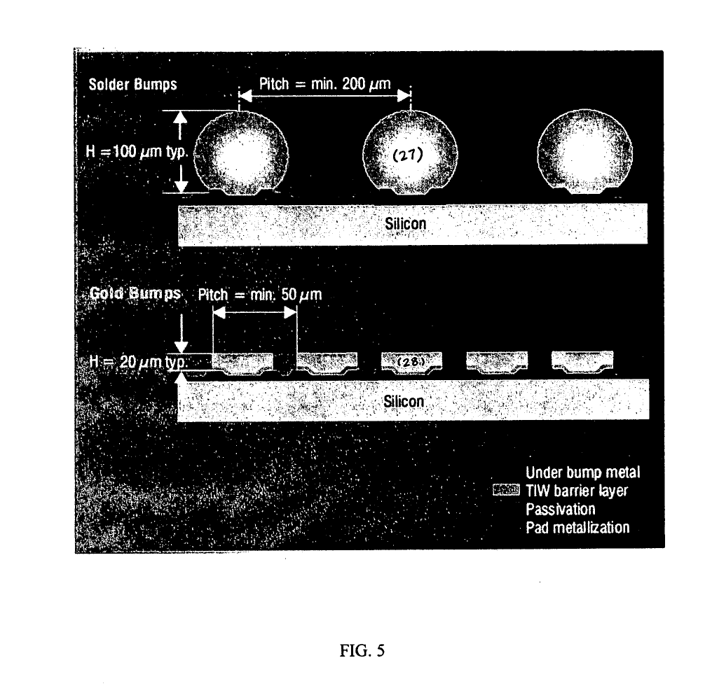

FIG. 5 illustrates an example of the relative size and spacing of solder 27 and gold bump 28 metallurgies and clearly defines the compact structure of gold bumps.

The on center line spacing for a gold bump structure is typically less than ¼ that of solder bumps and, therefore, the gold bump method can have an I/O interconnects that are at least 4 times that of solder bumps.

In accordance with a preferred embodiment of the present invention, silver alloys useful for the formation of the UBM and bump are comprised of greater than about 35% silver and up to about 65% of either gold and/or palladium. Silver and gold have the same atomic size and therefore, can interchange with each other's atomic spacing in a metal alloy. In contrast to silver alloys, pure silver cannot be used alone because it lacks sufficient corrosion resistance and also tends toward electro-migration in an electric field. Because of these factors other metals must be alloyed with silver while still retaining the preferred atomic lattice spacing and sufficient corrosion resistance for subsequent electroplating or other metallic deposition method.

Similarly, copper alloys useful for the formation of the UBM and bump are comprised of greater than about 60% copper with the balance of gold. Interestingly, too much gold in this alloy will lead to extreme hardness and subsequent failure in attaching the flip chip device to a gold plated circuit. Copper has an atomic diameter that is just slightly smaller than gold, but would work well in a total bump system comprised of copper and gold. Gold can also be alloyed with nickel to reduce cost and, in this embodiment, the gold content is greater than about 65% with the balance being nickel.

In another preferred embodiment, in addition to electroplating, as described herein and/or as known to those skilled in the art, thick metal layers can also be economically deposited by vacuum arc deposition or evaporation, a science similar to sputtering but here the metal is evaporated inside of a vacuum chamber and the cloud of evaporated metal is made to preferentially condense onto the substrate. This is an environmentally friendly process and a good alternative to electroplating.

The following examples and features are presented to illustrate the scope of the invention:

### EXAMPLE 1

A silver based alloy comprising about 10% gold.

### EXAMPLE 2

A silver based alloy comprising about 65% gold.

### EXAMPLE 3

A gold based alloy comprising about 30% nickel.

### EXAMPLE 4

A copper based alloy comprising about 35% gold.

### EXAMPLE 5

A silver based alloy comprising about 30% palladium.

### EXAMPLE 6

A silver alloy for forming a sputtered UBM seed layer containing from about 3% to 30% gold.

### EXAMPLE 7

A silver alloy for forming a sputtered UBM seed layer containing about 3 to 30% palladium.

### EXAMPLE 8

A silver alloy for forming a sputtered UBM seed layer comprising about 3% to 30% gold and about 3% to 30% palladium.

### EXAMPLE 9

A silver alloy for forming a sputtered UBM seed layer containing about 3 to 80% gold.

### EXAMPLE 10

A gold alloy for forming a sputtered UBM seed layer containing about 3 to 30% nickel.

### EXAMPLE 11

A gold alloy for forming a sputtered UBM seed layer containing about 3 to 30% palladium

### EXAMPLE 12

A gold alloy for forming a sputtered UBM seed layer containing about 3 to 30% nickel and about 3 to 30% palladium

### EXAMPLE 13

A silver alloy for forming a sputtered UBM seed layer containing 3 to 30% palladium.

### EXAMPLE 14

A copper alloy for forming a sputtered UBM seed layer containing about 3 to 40% gold

### EXAMPLE 15

A silver alloy for forming an electroplated or vacuum deposited bump containing about 3 to 30% gold.

### EXAMPLE 16

A silver alloy for forming an electroplated or vacuum deposited bump containing about 3 to 30% palladium.

### EXAMPLE 17

A silver alloy for forming an electroplated or vacuum deposited bump containing about 3 to 30% gold and about 3 to 30% palladium.

### EXAMPLE 18

A silver alloy for forming an electroplated or vacuum deposited bump containing about 3 to 80% gold.

### EXAMPLE 19

A gold alloy for forming an electroplated or vacuum deposited bump containing about 3 to 30% nickel.

### EXAMPLE 20

A gold alloy for forming an electroplated or vacuum deposited bump containing about 3 to 30% palladium.

### EXAMPLE 21

A gold alloy for forming an electroplated or vacuum deposited bump containing about 3 to 30% palladium and about 3 to 30% nickel.

While there has been described what is believed to be the preferred embodiment of the present invention, those skilled in the art will recognize that other and further changes and modifications may be made thereto without departing from the spirit of the invention. For example, certain aspects or embodiments of the invention include bumps and UBM seed layers having or using each of the foregoing examples, and semiconductor chips having or using such alloys. Also, the various components may be modified within the ranges generally set forth in the appended claims. In addition, certain aspects or embodiments of the invention include the process or method of making a UBM seed layer and/or bump with a gold or other alloy having one or more of the example compositions (e.g. by electroplating or vacuum depositing). Therefore, the invention is not limited to the specific details and representative embodiments shown and described herein. Accordingly, persons skilled in this art will readily appreciate that various additional changes and modifications may be made without departing from the spirit or scope of the invention.

What is claimed is:

1. A bump alloy, consisting of:
about 3-80% gold; and
the balance being silver.

2. The bump alloy as set forth in claim 1, consisting of:
about 3-30% gold.

3. The bump alloy as set forth in claim 1, consisting of:
about 10% gold.

4. The bump alloy as set forth in claim 1, consisting of:
about 65% gold.

5. A bump alloy, consisting of:
about 3-30% palladium; and
the balance being silver.

6. The bump alloy as set forth in claim 5, consisting of:
about 30% palladium.

7. A bump alloy, consisting of:
about 3-30% gold;
about 3-30% palladium; and
the balance being silver.

8. A bump alloy, consisting of:
at least about 60% copper; and
the balance being gold.

9. The bump alloy as set forth in claim 8, consisting of:
about 65% copper.

10. A bump alloy, consisting of:
at least about 65% gold; and
the balance being nickel.

11. The bump alloy as set forth in claim 10, consisting of:
about 3-30% nickel; and
the balance being gold.

12. The bump alloy as set forth in claim 11, consisting of:
about 30% nickel.

13. A bump alloy, consisting of:
about 3-30% palladium; and
the balance being gold.

14. A bump alloy, consisting of:
about 3-30% nickel;
about 3-30% palladium; and
the balance being gold.

15. An under bump metallization seed layer alloy, consisting of:
about 3-80% gold; and
the balance being silver.

16. The under bump metallization seed layer alloy as set forth in claim 15, consisting of:
about 3-30% gold.

17. The under bump metallization seed layer alloy as set forth in claim 15, consisting of:
about 10% gold.

18. The under bump metallization seed layer alloy as set forth in claim 15, consisting of:
about 65% gold.

19. An under bump metallization seed layer alloy, consisting of:
about 3-30% palladium; and
the balance being silver.

20. The under bump metallization seed layer alloy as set forth in claim 19, consisting of:
about 30% palladium.

21. An under bump metallization seed layer alloy, consisting of:
about 3-30% gold;
about 3-30% palladium; and
the balance being silver.

22. An under bump metallization seed layer alloy, consisting of:
at least about 60% copper; and
the balance being gold.

23. The under bump metallization seed layer alloy as set forth in claim 22, consisting of:
about 3-40% gold; and
the balance being copper.

24. The under bump metallization seed layer alloy as set forth in claim 23, consisting of:
about 35% gold.

25. An under bump metallization seed layer alloy, consisting of:
at least about 65% gold; and
the balance being nickel.

26. The under bump metallization seed layer alloy as set forth in claim 25, consisting of:
about 3-30% nickel; and
the balance being gold.

27. The under bump metallization seed layer alloy as set forth in claim 26, consisting of:
about 30% nickel.

28. An under bump metallization seed layer alloy, consisting of:
about 3-30% palladium; and
the balance being gold.

29. An under bump metallization seed layer alloy, consisting of:
about 3-30% nickel;
about 3-30% palladium; and
the balance being gold.

30. A semiconductor device, comprising:
a bump alloy consisting of:
about 3-80% gold; and
the balance being silver.

31. The semiconductor device as set forth in claim 30, comprising a bump alloy with about 3-30% gold.

32. The semiconductor device as set forth in claim 30, comprising a bump alloy with about 10% gold.

33. The semiconductor device as set forth in claim 30, comprising a bump alloy with about 65% gold.

34. A semiconductor device, comprising:
a bump alloy consisting of:
about 3-30% palladium; and
the balance being silver.

35. The semiconductor device as set forth in claim 34, comprising a bump alloy with about 30% palladium.

36. A semiconductor device, comprising:
a bump alloy consisting of:
about 3-30% gold;
about 3-30% palladium; and
the balance being silver.

37. A semiconductor device, comprising:
a bump alloy consisting of:
at least about 60% copper; and
the balance being gold.

38. The semiconductor device as set forth in claim 37, comprising a bump alloy with about 65% copper.

39. A semiconductor device, comprising:
a bump alloy consisting of:
at least about 65% gold; and
the balance being nickel.

40. The semiconductor device as set forth in claim 39, comprising a bump alloy with about 3-30% nickel; and the balance being gold.

41. The semiconductor device as set forth in claim 40, comprising a bump alloy with about 30% nickel.

42. A semiconductor device, comprising:
a bump alloy consisting of:
about 3-30% palladium; and
the balance being gold.

43. A semiconductor device, comprising:
a bump alloy consisting of:
about 3-30% nickel;
about 3-30% palladium; and
the balance being gold.

44. A semiconductor device, comprising:
an under bump metallization seed layer alloy consisting of:
about 3-80% gold; and
the balance being silver.

45. The semiconductor device as set forth in claim 44, comprising an under bump metallization seed layer alloy with about 3-30% gold.

46. The semiconductor device as set forth in claim 45, comprising an under bump metallization seed layer alloy with about 10% gold.

47. The semiconductor device as set forth in claim 44, comprising an under bump metallization seed layer alloy with about 65% gold.

48. A semiconductor device, comprising:
an under bump metallization seed layer alloy consisting of:
about 3-30% palladium; and
the balance being silver.

49. The semiconductor device as set forth in claim 48, comprising an under bump metallization seed layer alloy with about 30% palladium.

50. A semiconductor device, comprising:
an under bump metallization seed layer alloy consisting of:
about 3-30% gold;
about 3-30% palladium; and
the balance being silver.

51. A semiconductor device, comprising:
an under bump metallization seed layer alloy consisting of:
at least about 60% copper; and
the balance being gold.

52. The semiconductor device as set forth in claim 51, comprising an under bump metallization seed layer alloy with about 3-40% gold; and the balance being copper.

53. The semiconductor device as set forth in claim 52, comprising an under bump metallization seed layer alloy with about 35% gold.

54. A semiconductor device, comprising:
an under bump metallization seed layer alloy consisting of:
at least about 65% gold; and
the balance being nickel.

55. The semiconductor device as set forth in claim 54, comprising an under bump metallization seed layer alloy with about 3-30% nickel; and the balance being gold.

56. The semiconductor device as set forth in claim 55, comprising an under bump metallization seed layer alloy with about 30% nickel.

57. A semiconductor device, comprising:
an under bump metallization seed layer alloy consisting of:
about 3-30% palladium; and
the balance being gold.

58. A semiconductor device, comprising:
an under bump metallization seed layer alloy consisting of:
about 3-30% nickel;
about 3-30% palladium; and
the balance being gold.
